(19) United States
(12) Patent Application Publication
(10) Pub. No.: US 2009/0135142 A1
(43) Pub. Date: May 28, 2009

(54) DATA ENTRY DEVICE AND METHOD

(75) Inventors: Chia-Yu Fu, Chandler, AZ (US); Manuel Oliver, Scottsdale, AZ (US)

Correspondence Address: INGRASSIA FISHER & LORENZ, P.C. (MOT), 7010 E. Cochise Road, SCOTTSDALE, AZ, 85253, US

(73) Assignee: MOTOROLA, INC., Schaumburg, IL (US)

(21) Appl. No.: 11/945,331

(22) Filed: Nov. 27, 2007

(51) Int. Cl. H03K 17/969; G06F 3/02

(52) U.S. Cl. 345/168; 340/665; 327/517

(57) ABSTRACT

A method of entering data into an electronic device (110, 210) includes touching (902, 912) with continual pressure a touch input region (114). Feedback is received (904, 914, 916, 920, 922) indicating a plurality of input possibilities for selection, wherein the touch is released (906, 924) in response to the feedback (904, 914, 916, 920, 922) in one of a temporal or spatial displacement (918) to select one of the plurality of input possibilities.

### FIELD

The present invention generally relates to electronic devices and more particularly to a method and apparatus for selecting input into an electronic device.

### BACKGROUND

The method of user input to mobile electronic devices is an important element of the user experience. Historically, because of the small physical size of such devices, for example, cell phones, personal digital assistants, pagers, and media players, there is only limited area in which to deploy key input. For example, one common arrangement used for alphanumeric input is the 12 key Bell keypad. When in number entry mode, numbers can be entered with a single keystroke. However, when entering text the user may need to press a key multiple times to select a character. For example, the ABC2 key is pressed twice to select B. Although cumbersome, this is a predominant method of entering text on mobile phones today. An alternative is to make the devices larger so that qwerty keyboards can be used so that only a single keystroke is needed for each key. With the trend in mobile electronic devices towards larger displays, the area for keypads may become more constrained.

In addition to conventional keypads that may employ mechanical dome switches, other types of user input are being deployed on mobile electronic devices. These include touch sensors that detect the presence of a finger by capacitive, optical, resistive, or other physical means. Force or pressure sensors such as force sensitive resistors can be used to supplement touch sensors to discriminate between different levels of force applied to a touch sensor. In addition, haptic feedback is often used in conjunction with such devices to provide user feedback to confirm a keypress when such touch interfaces are used.

Accordingly, it is desirable to leverage these newer user interface technologies to overcome the limited area available on the surface of mobile devices to provide a better user input experience. Furthermore, other desirable features and characteristics of the present invention will become apparent from the subsequent detailed description and the appended claims, taken in conjunction with the accompanying drawings and this background.

### BRIEF DESCRIPTION OF THE DRAWINGS

Embodiments of the present invention will hereinafter be described in conjunction with the following drawing figures, wherein like numerals denote like elements, and

FIG. 1 is an isometric view of a portable electronic device in accordance with an exemplary embodiment;

FIG. 2 is a block diagram of a portable electronic device in accordance with an exemplary embodiment;

FIG. 3-4 are cross section views of a known apparatus providing haptic feedback to the portable electronic device;

FIG. 5 is a cross section of a keyboard usable with the exemplary embodiments;

FIGS. 6-8 are views of finger movement entering characters on a keyboard in accordance with an exemplary embodiment;

FIG. 9 is a flow chart of the steps of the exemplary embodiment of FIGS. 6-8;

FIGS. 10-12 are views of finger movement entering characters on a keyboard in accordance with another exemplary embodiment; and

FIG. 13 is a flow chart of the steps of the exemplary embodiment of FIGS. 10-12.

### DETAILED DESCRIPTION

The following detailed description is merely exemplary in nature and is not intended to limit the invention or the application and uses of the invention. Furthermore, there is no intention to be bound by any theory presented in the preceding background or the following detailed description.

An apparatus and method described herein integrates, in three embodiments, time, location, and pressure sensing with haptic feedback to simplify the physical workload associated with user input on a keypad or touchscreen. The force, or haptic, feedback preferably is similar to that experienced by a user when pressing and releasing a key. Upon pressing down, a first feedback is experienced that may be a click or short vibration, and subsequent events may also result in additional clicks or short vibrations. One exemplary embodiment improves on the known multitap method of data entry. Instead of multiple key presses on a touch input region, such as a key, to select an input possibility, for example, three presses for selecting “C” on the “ABC2” key, a finger presses the key and releases the key after the desired number of haptic clicks is sensed. Releasing the key after the first haptic click results in an “A” being selected. In the case of selecting a “C”, the finger would be pressed continuously against the “ABC2” key, and released upon sensing the third click. Optionally audio feedback may accompany the key selection as well. This audio feedback may be in the form of an audible click or can be a description of the current selection, for example a voice saying the letter “A.” Although the exemplary embodiments described herein refer to text or alphanumeric selection, any character, data, or input command may be selected by this method.

Another exemplary embodiment involves the application of two or more levels of force applied to the key for selection of the appropriate character. For example, application of a lower force on the “ABC2” key would select the “A”, while application of a greater force would select the “B”. Haptic feedback is provided to assist the user in determining the level of the applied force. One example would be to provide a click feedback as the user exceeds each pressure threshold. Another example would be to provide different types of feedback (e.g. different waveforms or amplitudes) for each pressure range.

In another embodiment, the finger is placed on the desired key and an image appears on the screen indicating the desired selections. The first character is highlighted when the finger is pressed against the key. As the finger moves across the keypad, the cursor moves to another character on the screen. The finger is released from the keypad when the desired character is highlighted on the screen. Optionally, haptic feedback is provided each time another character is highlighted, providing additional information to the user about which character is highlighted.

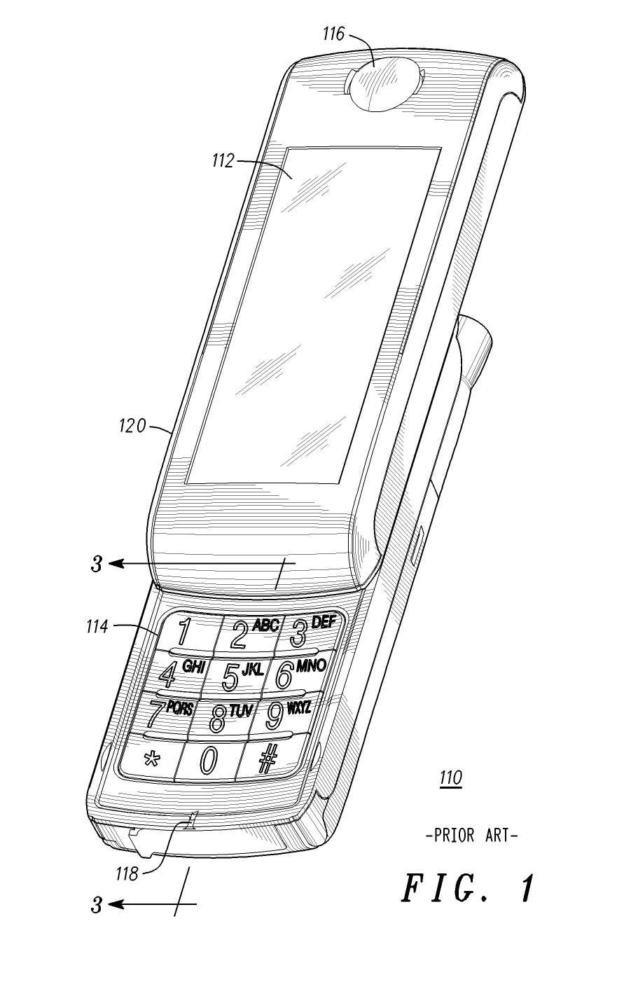

FIG. 1 shows in schematic form a known mobile communication device, which may be used with the exemplary embodiments of an electronic device 110 described herein, and includes a display 112, a control panel 114, a speaker 116, and a microphone 118 formed within a housing 120. Conventional mobile communication devices also include, for example, an antenna and other inputs which are omitted from the figure for simplicity. Circuitry (not shown) is coupled to each of the display 112, control panel 114, speaker 116, and microphone 118. Although this embodiment describes a mobile communication device, the electronic device 110 can take other forms such as a laptop computer, personal digital assistant (PDA), digital camera, or a music/video playback device (e.g., MP3/MP4 player). It is also noted that the portable electronic device 110 may comprise a variety of form factors, for example, a “foldable”, or flip, cell phone.

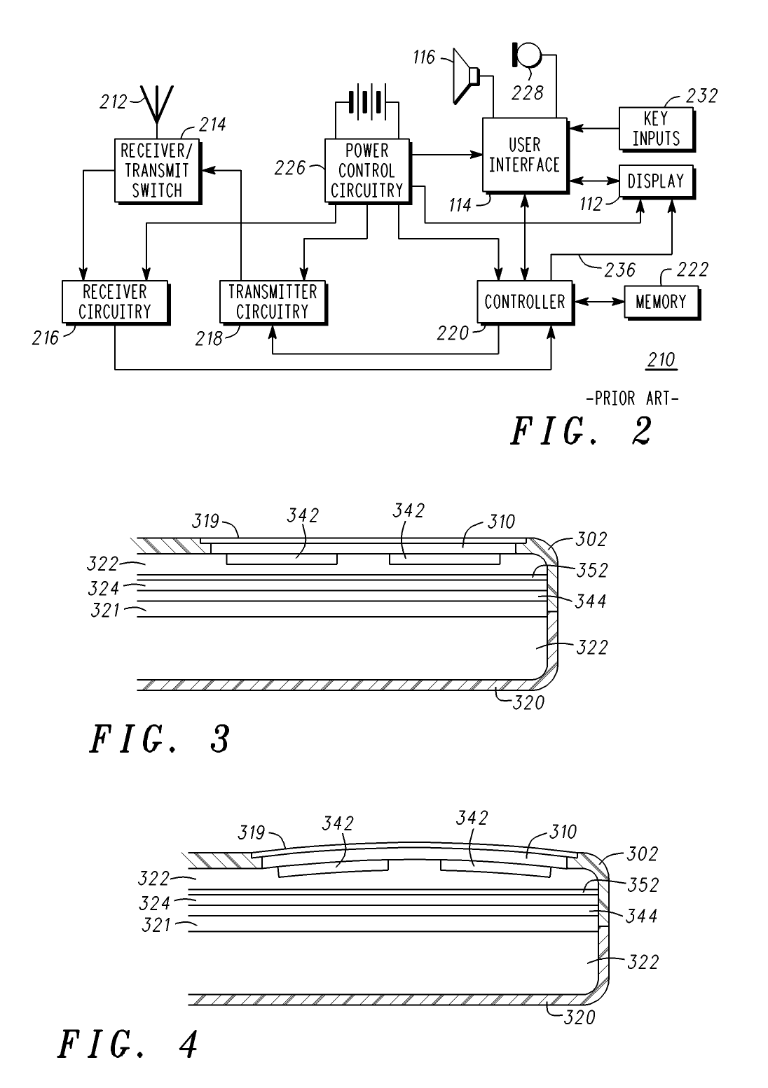

Referring to FIG. 2, a block diagram of a known portable electronic device 210 such as a cellular phone, in accordance with the exemplary embodiment is depicted. Though the exemplary embodiment is a cellular phone, the invention described herein may be used with any electronic device in which information is to be presented. The portable electronic device 210 includes an antenna 212 for receiving and transmitting radio frequency (RF) signals. A receive/transmit switch 214 selectively couples the antenna 212 to receiver circuitry 216 and transmitter circuitry 218 in a manner familiar to those skilled in the art. The receiver circuitry 216 demodulates and decodes the RF signals to derive information therefrom and is coupled to a controller 220 for providing the decoded information thereto for utilization thereby in accordance with the function(s) of the portable communication device 210. The controller 220 also provides information to the transmitter circuitry 218 for encoding and modulating information into RF signals for transmission from the antenna 212. As is well-known in the art, the controller 220 is typically coupled to a memory device 222 and a user interface 114 to perform the functions of the portable electronic device 210. Power control circuitry 226 is coupled to the components of the portable communication device 210, such as the controller 220, the receiver circuitry 216, the transmitter circuitry 218 and/or the user interface 114, to provide appropriate operational voltage and current to those components. The user interface 114 includes a microphone 228, a speaker 116 and one or more key inputs 232, including a keypad. The user interface 114 may also include a display 112 which could include touch screen inputs. The display 112 is coupled to the controller 220 by the conductor 236.

Many methods of providing haptic feedback are known that may be used with the methods described herein, including the haptic feedback apparatus described in U.S. patent application Ser. No. 11/590,494, assigned to the Assignor of this application. In that previously filed application, a piezoelectric ceramic element or multiple piezoelectric ceramic elements are directly bonded to the backbone structure of portable devices, for example the metal or plastic chassis of a cell phone. A chassis of a cell phone provides structural rigidity to the phone and serves as a structure plate for the attachment of most phone modules and components. The piezoelectric ceramic elements and an input device, e.g., a morphable user interface, are bonded to opposite sides of the chassis in one exemplary embodiment. Upon application of an electric field, the in-plane shrinkage or expansion of the piezoelectric elements causes localized flexing motion of the chassis and provide tactile feedback at the interface of the input device. The input device is not directly pushed or pulled by separated piezoelectric bender actuators as described in the prior art, but is part of the structure deformed (flexed) by the integrated piezoelectric ceramic elements. The motion of the input device is flexing, rather than an up/down movement by multiple piezoelectric actuators actuating at multiple points. The benefit of the approach is that it does not require precise mechanical alignment of an actuating element with the structure that is being pushed or pulled.

At least one piezoelectric actuator e.g., a piezoelectric bender, is bonded directly to a metal plate abutting the input device for which the haptic feedback is intended. This direct placement provides flextensional bending movement of the input device, and thus provides tactile feedback including true key click like tactile feedback to a user. This displacement of the input device is small, only 1.0 to 30.0 micrometers.

Piezoelectric actuators are uniquely capable of delivering fast, e.g., 1.0 to 10.0 milliseconds, high acceleration, e.g., 1-100 g, response needed to simulate key click responses. Piezoelectric actuators are also able to provide a broadband movement (1-2000 Hz) as opposed to fixed frequency response of resonant electromagnetic vibration motors.

The piezoelectric elements shrink or expand in the lateral direction when subject to an electric field, causing a much amplified perpendicular movement in its center with the constraint from being bonded to a hard surface, such as a phone chassis. The piezoelectric elements can be driven by a wide range of waveforms to tailor mechanical output to the user. A high slew rate step function can provide the highest acceleration and click-like feedback. Alternatively, multiple sine-waves can be used to generate feedback that might characterized as a buzz. Piezoelectric actuators can also be operated in a wide frequency range, allowing broadband haptic responses. Power consumption of piezoelectric actuators is generally comparable to or less than that of DC rotary motors. The actuators' latency (the time required to ramp up to full speed) is small enough to allow users to have nearly instantaneous response in interactive applications.

FIGS. 3 and 4 are cross sectional views taken along line 3-3 of the portable electronic device 110 of FIG. 1. The portable electronic device 300 comprises a housing 302 supported on a chassis 322. Piezoelectric actuators 342 are positioned within recesses of the chassis 322 and directly against the input device 310. A conductive bonding material (not shown) is positioned between the input device 310 and the piezoelectric actuators 342 for securing the two together and providing power to the piezoelectric actuators 342. A layer 344 of mylar is positioned between a battery floor 321 and a printed circuit board 324. An air gap 352 allows for movement of the chassis 322, piezoelectric actuators 342, user interface 310, and transparent cover 319. FIG. 4 illustrates the portable electronic device 300 with power applied to the piezoelectric actuators 342 and the resulting flexing of the chassis 322, input device 310, and transparent cover 319.

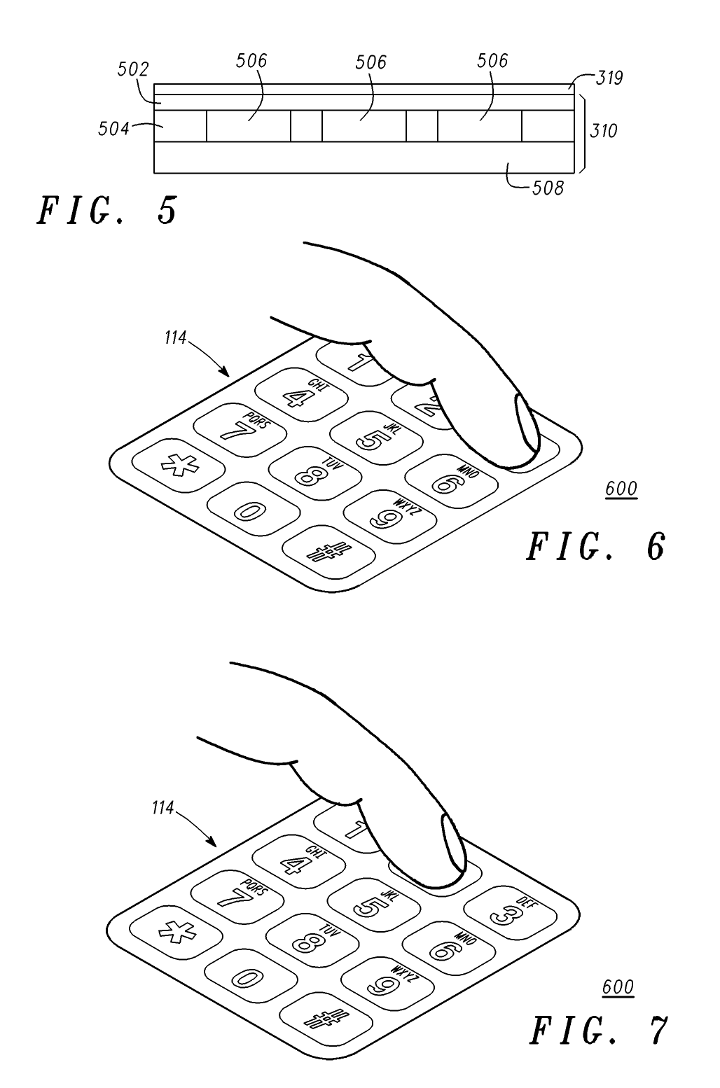

FIG. 5 shows the input device in more detail, including a location sensor 502 positioned between the transparent cover 319. The user interface 310 may include a number of functional elements that can display information to the user and receive touch input from the user. The stack-up of the element can differ depending on the technologies selected and the method in which they are integrated. Information may be presented by simple printed graphics which may contain a backlight to illuminate the graphics in low light conditions. Optionally, the keypad graphics may be electronically changeable using switchable reflective or emissive display technologies such as liquid crystal displays or organic light emitting diodes. The user touch input may be captured by (1) simple mechanical dome switches that connect electrical conductors on a printed circuit board, (2) location sensing technologies such as resistive, capacitive, or optical touchpads, (3) or force sensing technologies such as force sensitive resistors, piezoresistive elements, or strain gauges, or combinations of the above. The particular stack-up in FIG. 5 contains a backlit keypad graphic layer 502 positioned above a resistive touch sensor layer 504, 506 that combines both position and force sensing that resides on the support layer 508.

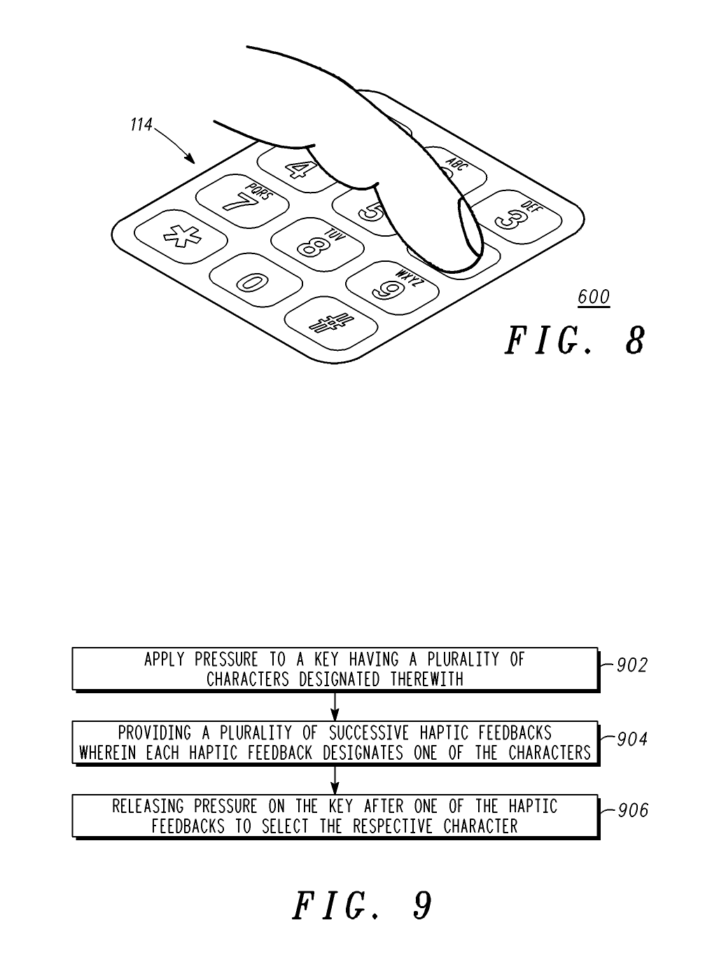

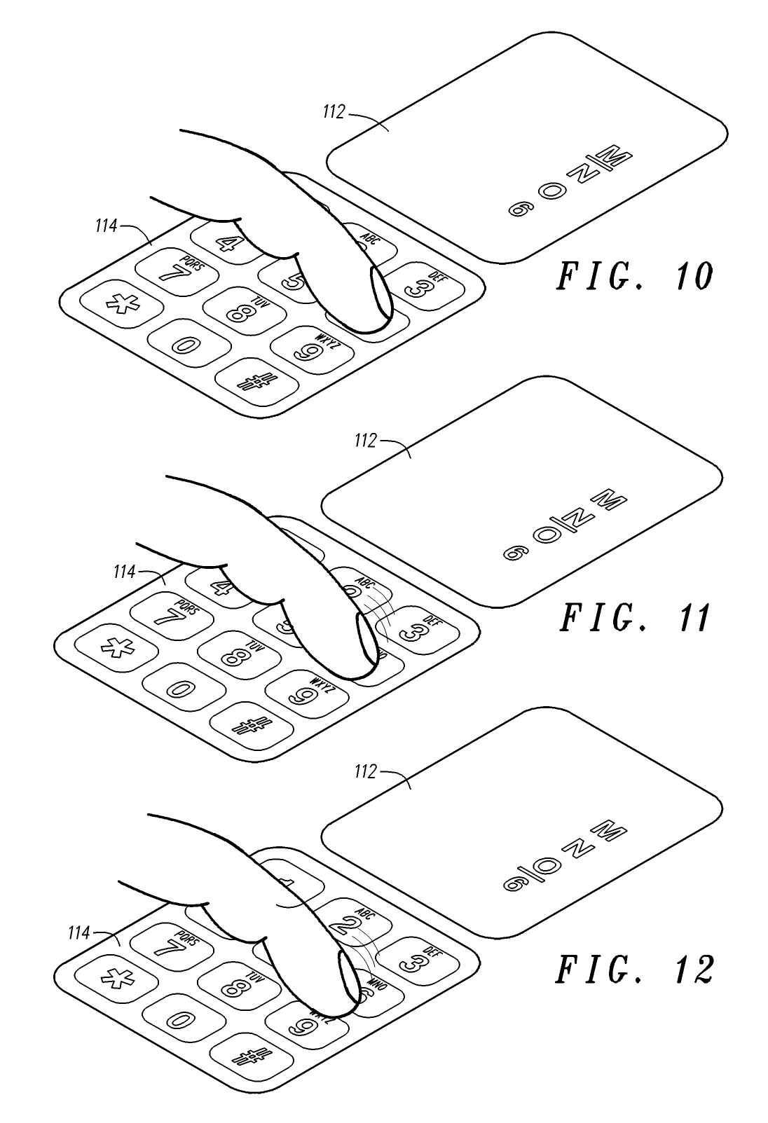

FIGS. 6-8 show a first exemplary embodiment wherein a finger is positioned and held on a key. As an example, the user desires to spell “FAN” using the keyboard 600. Referring to FIG. 6, pressure is applied and held on the key DEF3 (step 902 of FIG. 9). Software in the controller 220 selects the first letter “D” and causes the piezoelectric actuators 342 to provide a first click (step 904). Releasing the finger immediately after the first click would include the “D” in the message being constructed (step 906). However, continued pressure by the finger and after a short span of time, the controller 220 selects the next letter “E” and instructs the piezoelectric actuators 342 to provide a second click (step 904). Continued pressure for another short span of time would cause the controller 220 to select the next letter “F” and instruct the piezoelectric actuators 342 to provide a third click (step 904). Releasing pressure by the finger on the keyboard 114 after the third click would select the “F” for the message (step 906). In FIG. 7, pressure from the finger is applied to the ABC2 key and released after one click to select the “A”. In FIG. 8, pressure is applied to the MNO6 key and released after two clicks to select the “N”, thereby spelling the word “FAN”.

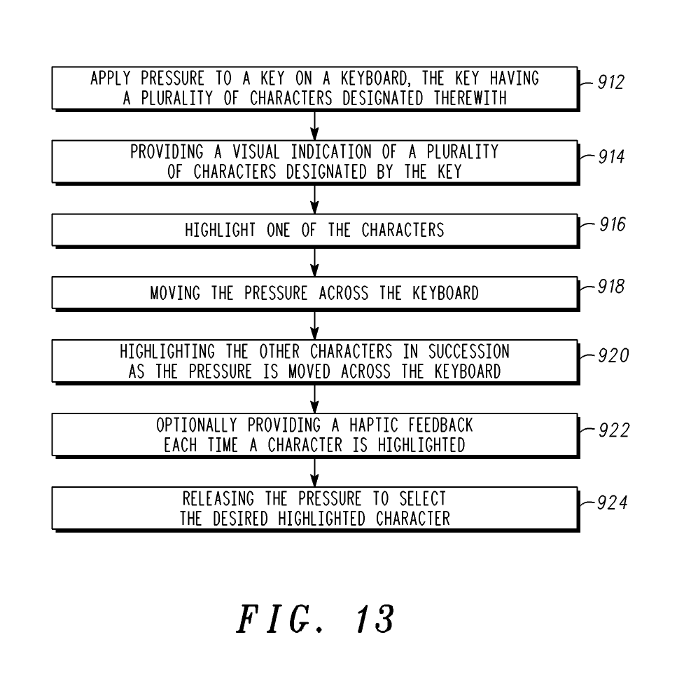

FIGS. 10-12 describe a second exemplary embodiment wherein pressure is applied by a finger positioned on the MNO6 key (step 906 of FIG. 13). When pressure is applied to the MNO6 key, the pop-up image “MNO6” appears on the screen 112 (step 914). Software in the controller 220 selects the first letter “M”, highlights (step 916) the M (such as with a cursor as shown) and optionally causes the piezoelectric actuators 342 to provide a first click (step 922). Releasing the finger without any movement of the finger would include the “M” in the message being constructed (step 924). However, moving (step 918) the finger in the direction of the next letter “N” on the keypad causes it to be highlighted (step 920), and the piezoelectric actuators 342 to optionally provide a second click (step 922). Continued movement of the finger on the keyboard 114 would cause the controller 220 to highlight the next letter “0” and optionally instruct the piezoelectric actuators 342 to provide a third click. Releasing (step 924) pressure by the finger on the keyboard 114 while the third letter “0” is highlighted (and after the third click is provided) would select the “0” for the message.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. A method of providing user input into an electronic device, comprising:
touching with continual pressure a touch input region;
receiving feedback from the electronic device indicating a plurality of input possibilities for selection; and
releasing the continual pressure in response to the feedback in one of a temporal, force, or spatial displacement to select one of the plurality of input possibilities.

2. The method of claim 1 wherein the receiving feedback step comprises receiving a plurality of haptic indications, each haptic indication representing one of the plurality of inputs.

3. The method of claim 1 wherein the receiving feedback step comprises receiving a plurality of haptic indications, each haptic indication representing one of the plurality of characters and each haptic indication having an increasing intensity.

4. The method of claim 1 wherein the touching step comprises touching a character entry member of a keypad on a mobile communications device.

5. The method of claim 1 wherein the receiving feedback step comprises receiving a visual indication on a display screen.

6. The method of claim 1 wherein the receiving feedback step comprises receiving a visual indication of the plurality of input possibilities.

7. The method of claim 6 wherein the visual indication step comprises highlighting one of the plurality of characters as determined by the spatial displacement of the touch.

8. The method of claim 1 wherein the receiving feedback step comprises receiving an audio indication of the plurality of input possibilities.

9. A method of entering data into an electronic device, comprising:
touching with continual pressure a touch input region;
receiving a plurality of successive haptic indications, each of the indications representing a different input; and
releasing the continual pressure after one of the haptic indications, thereby selecting the input represented by the one of the haptic indications.

10. The method of claim 9 wherein the receiving step comprises receiving a plurality of haptic indications, each haptic indication representing one of the plurality of characters and each haptic indication having an increasing intensity.

11. The method of claim 9 wherein the touching step comprises touching a character entry member of a keypad on a mobile communications device.

12. The method of claim 9 wherein the receiving step further comprises receiving a visual indication on a display screen.

13. The method of claim 9 wherein the receiving step further comprises receiving a visual indication of the plurality of input possibilities.

14. The method of claim 13 wherein the visual indication step comprises highlighting one of the plurality of inputs as determined by the spatial displacement of the touch.

15. The method of claim 9 wherein the receiving feedback step comprises receiving an audio indication of the plurality of input possibilities.

16. A method of entering data into an electronic device, comprising:
touching with continual pressure a input entry member disposed on a touch screen;
presenting a visual indication of a plurality of inputs, one of the inputs being visually identified;
moving the continual pressure across the touch screen, thereby causing another of the plurality of inputs to be visually identified; and
releasing the touch to select the visually identified input.

17. The method of claim 16 further comprising providing a haptic response with the visual identification of each of the plurality of inputs.

18. The method of claim 16 further comprising receiving a plurality of haptic indications, each haptic indication representing one of the plurality of inputs.

19. The method of claim 16 further comprising receiving a plurality of haptic indications, each haptic indication representing one of the plurality of inputs and each haptic indication having an increasing intensity.

20. The method of claim 16 wherein the touching step comprises touching a character entry member of a keypad on a mobile communications device.

21. The method of claim 16 wherein the presenting step comprises presenting a visual indication on a display screen.

22. The method of claim 16 wherein the presenting step comprises highlighting one of the plurality of inputs as determined by the spatial displacement of the touch.

23. The method of claim 16 further comprising receiving an audio indication representing each of the plurality of inputs.
